(19) United States
(12) Patent Application Publication
(10) Pub. No.: US 2010/0225387 A1
(43) Pub. Date: Sep. 9, 2010

(54) FM demodulator apparatus and method includes an amplitude locked loop and a delay-line quadrature detector without the use of a limited amplifier

(76) Inventor: Archibald McGilvray Pettigrew, (US)

Correspondence Address: AMPSYS Electronics Ltd., Studio 253, Embroidery Mill, Abbey Mill Business Centre, Paisley, PA1 1TJ, omitted

(21) Appl. No.: 12/398,199

(22) Filed: Mar. 5, 2009

(51) Int. Cl. H03D 3/00

(52) U.S. Cl. 329/315

(57) ABSTRACT

The present invention relates to an FM demodulator incorporating a delay-line quadrature detector without the use of a limiter amplifier. An Amplitude Locked Loop circuit provides a carrier signal with no amplitude variation prior to performing a conversion from frequency modulation to phase modulation. A delay-line performs this conversion using a standard IF ceramic filter with a precise delay of 90 degrees to the un-modulated carrier frequency. The original non-delayed carrier is multiplied with the delayed carrier using a four quadrant linear multiplier to generate a demodulated audio output.

### CROSS REFERENCE TO RELATED APPLICATIONS

| | |
|---|---|
| Title: | Amplitude Locked Loop Circuits |
| Publication No.: | U.S. Pat. No. 5,341,106 |
| Publication Date: | 1994 Aug. 23 |
| International Filing Date: | 23 Jan. 1991 |
| Title: | Amplitude Locked Loop Circuits |
| Publication No.: | WO/91/011854 |
| Publication Date: | 1991 Aug. 8 |
| International Filing Date: | 23 Jan. 1991 |
| International Application No.: | PCT/GB1991/000101 |

### FIELD OF THE INVENTION

The invention relates to an FM demodulator incorporating an amplitude locked loop circuit and a delay-line quadrature detector while eliminating the use of a conventional limiter.

### DESCRIPTION OF PRIOR ART

In the art of FM demodulation, the two most common forms of circuit for demodulation are known as the quadrature detector and the phase locked-loop. Both are well described in the literature and no attempt will be made to add to this body of knowledge. While electronic circuits to perform the demodulation of frequency-modulated signals have been known since the mid-thirties of last century, all of these types of circuit suffered from the same disadvantages. They require that the input carrier signal be amplified until hard limiting takes place. No type of FM demodulator could operate successfully with pre-limiting the input signal, including the phase locked loop type of demodulator.

With the invention of the amplitude locked loop (ALL) [U.S. Pat. No. 5,341,106 and WO/91/011854], a new type of FM demodulator was required which could operate without a constant envelope input signal. It is the purpose of this patent to describe an FM demodulator that will operate in a satisfactory manner without the need for hard pre-limiting of the carrier signal.

### SUMMARY OF THE INVENTION

In accordance with the first aspect of the present invention there is provided an FM demodulator incorporating a delay-line quadrature detector (DQD) without the use of a limiter amplifier. According to another aspect of the invention the frequency modulation is converted to phase modulation comprising a delay-line, said delay-line comprises a standard IF ceramic filter with a delay of 90 degrees to the un-modulated carrier frequency. According to another aspect of the invention the delayed carrier output is multiplied by the original non-delayed carrier to generate a demodulated audio output

### BRIEF DESCRIPTION OF THE DRAWINGS

The accompanying drawings illustrate various embodiments of the principles described herein and are a part of the specification. The illustrated embodiments are merely examples and do not limit the scope of the claims.

FIG. 1 shows a diagram of a conventional FM demodulator incorporating the use of limiters.

FIG. 2 shows a diagram of the components of a delay-line quadrature detector (DQD) circuit, according to principles described herein.

FIG. 3 shows a waveform diagram of an FM carrier subject to Suppressed Carrier Amplitude Modulated FM and also the output of this signal after being passed through an Amplitude Locked Loop, according to principles described herein.

FIG. 4 shows a waveform diagram of the direct carrier signal and a delayed carrier signal, according to principles described herein.

FIG. 5 shows a waveform diagram of the delayed carrier signal and a multiplication product of the original carrier signal and the delayed carrier signal, according to principles described herein.

FIG. 6 shows a diagram of the delayed carrier signal and a multiplication product of the original carrier signal and the delayed carrier signal, according to principles described herein.

FIG. 7 shows waveform diagrams of the transmitted carrier signal with a constant envelope; the suppressed carrier amplitude modulated (SCAM) FM carrier after correction by automated gain control (AGC); the output from the amplitude locked loop (ALL); the output of the unfiltered DQD circuit; and the final filtered audio signal.

### DETAILED DESCRIPTION

A quadrature demodulator is common in FM demodulation for provision of good signal to noise ratio of the demodulated audio output while maintaining low product costs. This technology is described briefly as a means of introducing the concepts behind the new demodulator.

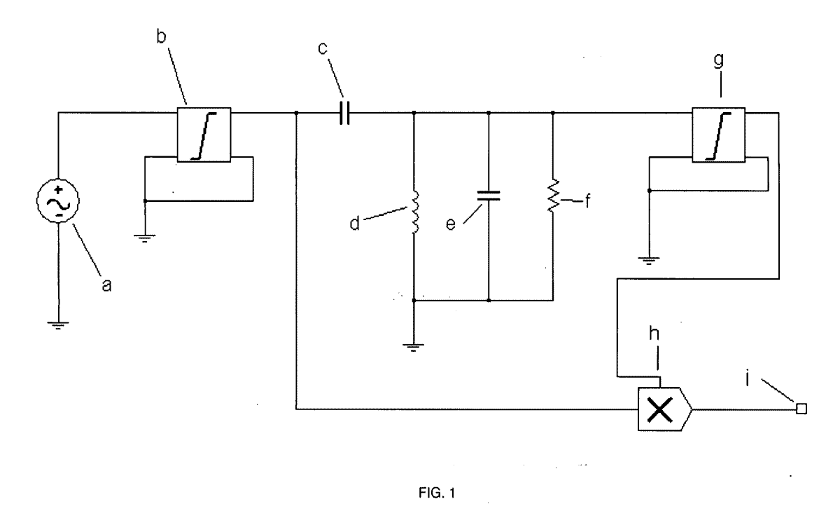

The standard quadrature demodulator FIG. 1) consists of a limiter amplifier (1b) to convert the carrier (1a) to a fixed amplitude signal, a direct path to a multiplier stage (1h). An inductor, capacitor and resistor tank network (1c-1f) convert the frequency modulation to phase variation prior to being applied to a second limiter (1g) where the frequency phase path and the direct path are multiplied to produce the demodulated audio signal (1i). The frequency-to-phase circuit establishes ninety degrees phase shift at the un-modulated carrier frequency and maintains a linear frequency-to-phase transfer function up to two or three times the maximum expected modulation depths, say in standard broadcasting, plus or minus 75 kHz. The two inputs voltages are like orthogonal vectors to each other at the carrier frequency. A dc voltage is produced when the carrier deviates a small amount from this zero point in the modulation. Increasing the ‘Q’ value of the tank circuit until phase linearity is lost at the extremes of modulation increases the sensitivity of the demodulator. This type of demodulator relies heavily on the action of the hard limiter amplifier to remove the amplitude variations, not only in the received carrier, but also in the second phase-frequency path. Any amplitude variation in either the direct path or the indirect path would result in severe distortion of the final audio signal.

During periods of multi-path reception, the FM modulation forms a second type of modulation of the carrier envelope, namely, suppressed carrier amplitude modulation (SCAM) of the original FM carrier. During this SCAM event, the carrier amplitude goes instantaneously to zero as the modulation goes to zero, and then reverses its phase. This step change in phase of one hundred and eighty degrees causes a large spike when passed through the differentiator process of the demodulator. This destructive spike has been misinterpreted in the past to be caused by threshold effects, which is quite erroneous. When the carrier goes to zero, the amplitude locked loop (ALL) cannot maintain lock and all feedback control is lost. The ALL becomes a fixed gain amplifier of say five times. This variation in amplitude is passed to the quadrature demodulator, resulting in even more distortion in the audio output since the phase shift network would become meaningless without constant input amplitude.

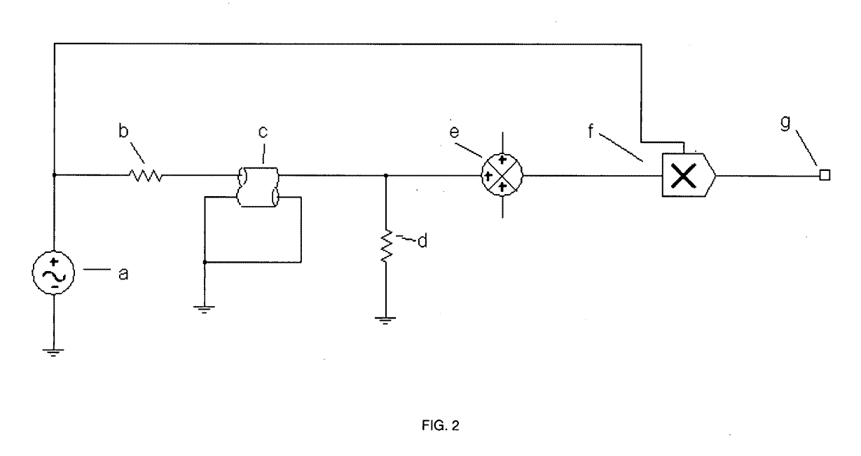

The solution to this dilemma is to design a perfect frequency-to-phase converter circuit and use a four quadrant linear multiplier for the final demodulation. The most perfect frequency-to-phase converter is a pure delay-line, where the delay is tuned to a ninety degree phase shift at the un-modulated carrier frequency. This technique is shown in FIG. 2). Fortunately, this circuit can be implemented in a very simple and economic manner using the by-product of a simple ceramic filter used in all radio intermediate frequency stages. A ceramic filter is designed as a near perfect delay-line and can be used as such in this demodulator implementation. In the analysis of this technique, the demodulation can occur at any multiple of π/2 radians or (2n−1) π/2 up to a limit of about an n value of 50. Using an n value of say 25 gives a multiplication or gain factor in the demodulated output of this number, or 28 dB over the simple π/2 delay factor. The final implementation is a demodulator with simple low cost components and a large signal strength output.

Further analysis shows that when the input carrier is amplitude modulated, as happens in SCAM episodes, a cubic relationship develops spontaneously between the required linear output and the measured output. This is a highly distorted function and of no value.

When the ALL is in lock, the carrier envelope is held constant by the feedback action. This flat envelope removes the non-linear cubic function and satisfactory performance is achieved. However, when the ALL loses lock, the cubic function returns. This is at the very same moment when the spike is forming in the output. A cubic function exhibits a phenomenon similar to crossover or dead zone distortion as the carrier passes through zero. The two functions partly cancel each other and the spike is greatly reduced or removed. Although this is an advantage at echo values approaching equal amplitude to the direct carrier amplitude, as the size of the echo reduces, the ALL will re-lock and linear operation will return. The spike discontinuity and severe distortion are re-introduced when this occurs.

With reference to the drawings, FIG. 1 shows a typical industry standard quadrature detector. The FM carrier input signal (1a) is applied to a limiting amplifier (1b), before being passed through a small series capacitor (1c), and tank circuit (1d, 1e, 1f). A second limiter circuit (1g) removes amplitude variations caused by the tank circuit. The original signal from the first limiter and the signal from the tank circuit and second limiter are then applied to a multiplier (1h) to provide a demodulated audio signal (1i).

FIG. 2 shows the basic circuit diagram of the delay-line quadrature demodulator comprising the carrier input (2a), a matched delay line ceramic filter (2b, 2c, and 2d) shown as a pure delay line, a simple times two buffer (2e), a linear multiplier (2f), to provide a demodulated output (2g) prior to audio baseband filtering.

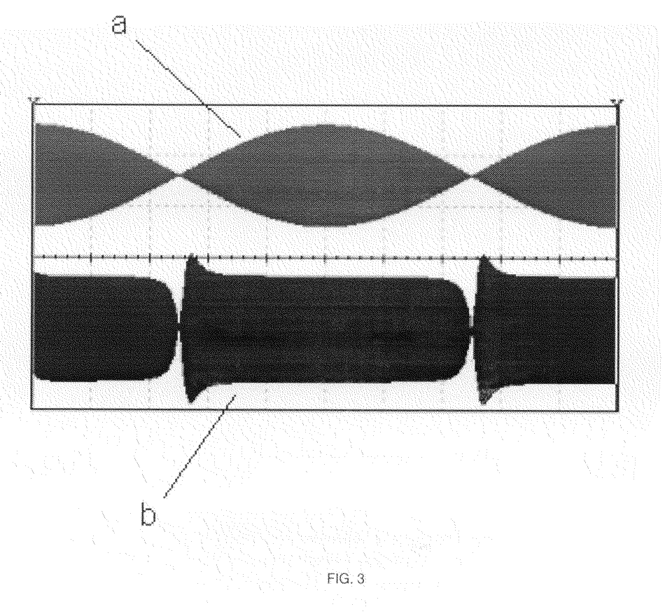

FIG. 3a) shows the carrier during an episode of suppressed carrier amplitude modulated FM (SCAM) where the frequency modulation has also become amplitude modulation due to the presence of a single echo of equal amplitude to the direct carrier and whose delay is exactly 180 degrees at the un-modulated carrier frequency. FIG. 3b) shows the output of the amplitude locked-loop (ALL). This waveform has a constant envelope until the input becomes so small that the ALL loses lock and the output follows the input down to zero carrier level.

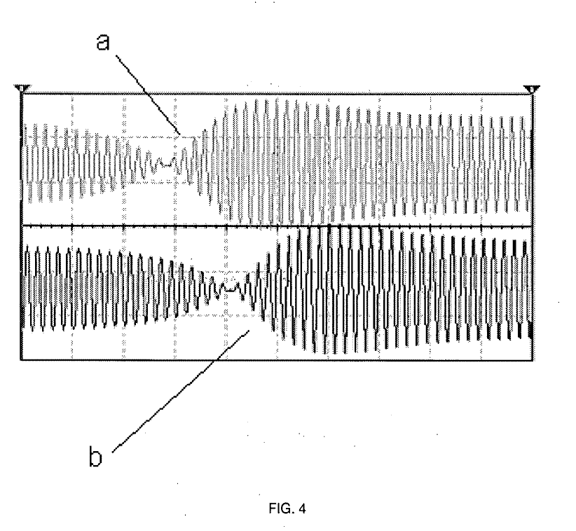

Referring now to FIG. 4 the image shows an expanded version of the direct carrier signal (4a) and the delayed carrier (4b). The delay time can be any odd multiple of the one quarter or three quarters of the carrier period. For example, if the carrier were 10 MHz then the delay could be 25 nanoseconds or 75 nanoseconds or any integer higher up to about fifty times. The typical value for good performance is 625 nanoseconds to obtain the quadrature condition in the title.

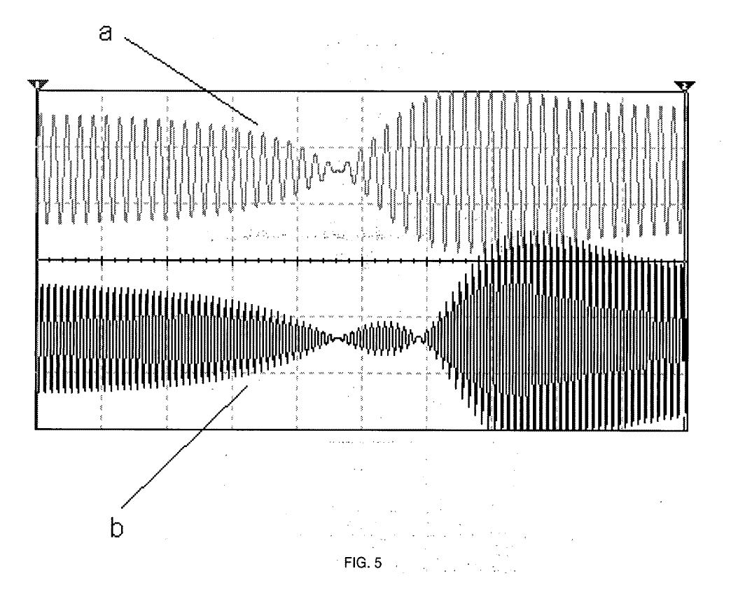

Referring now to FIG. 5 the upper trace shows delayed carrier (5a) and the multiplier output product (5b) of the original carrier and the delayed carrier. The first zero node is caused when the direct carrier changes phase by 180 degrees and the second zero node is caused by the delayed carrier changing phase by 180 degrees. The frequency of this output is twice the value of the input, say 20 MHz

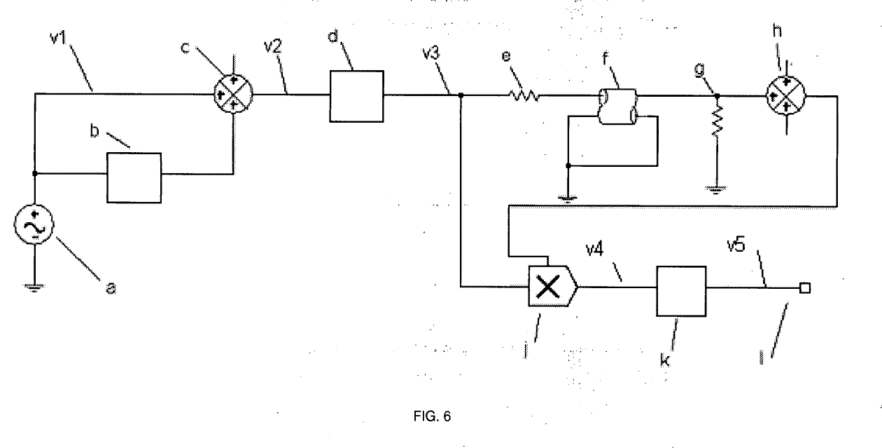

Referring now to FIG. 6, the ideal carrier with no envelope modulation (6a) is delayed by 180 degrees at the carrier frequency to provide a free space delay (6b). Both the direct and loss-free echo carrier signals are added (6c), before passing through the Amplitude Locked Loop (6d). The carrier is then delayed by 90 degrees or odd integer multiple thereof using the ceramic filter delay line. The original signal (6v3) is multiplied by the delayed signal which forms the delay-line quadrature detector output. This is passed through a baseband filter (6k) to provide the final audio output (6l).

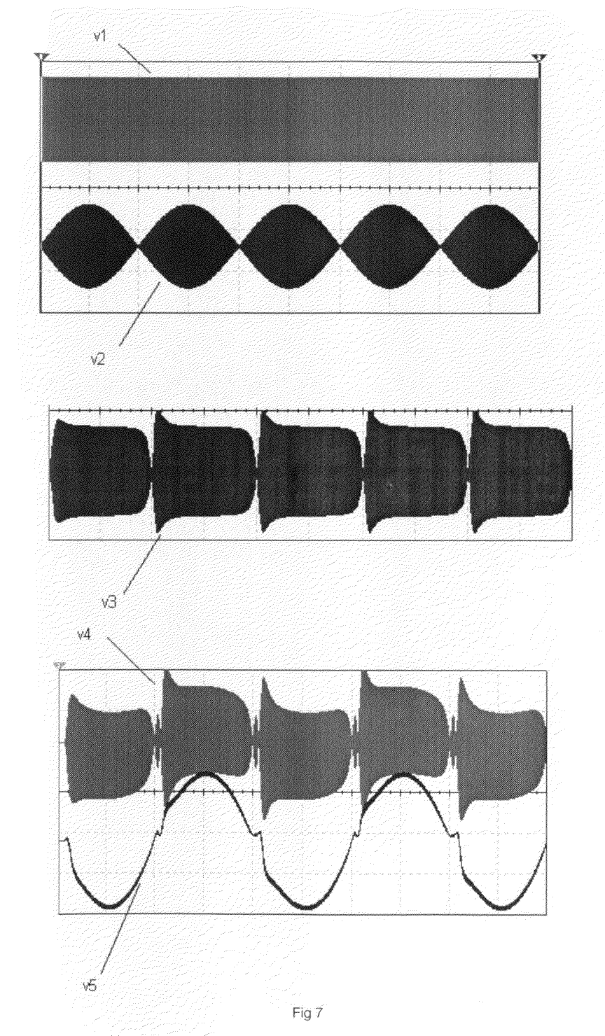

Referring now to FIG. 7, the first trace (v1) represents the transmitted carrier with a constant envelope, the second trace (v2) represents the suppressed carrier amplitude modulated (SCAM) FM carrier after correction by automatic gain control (AGC). The third trace represents the output from the amplitude locked loop (v3). The fourth and fifth traces represent the output of the unfiltered DQD circuit (v4) and the final filtered audio signal.

What is claimed is:

1. Apparatus for demodulating radio frequency signals without the use of a limiting amplifier circuit.

2. The apparatus in claim 1 is defined as an FM demodulator.

3. The apparatus in claim 1, wherein the FM demodulator further includes a delay line in the form or an IF ceramic filter.

4. The apparatus in claim 1, wherein the FM demodulator further includes the use of the amplitude locked loop circuits to minimise envelope variation in the received carrier.

5. The apparatus of claim 3 is defined as a Delay-line Quadrature Detector.

6. A method of demodulating an FM signal subject to multi-path or SCAM-FM conditions, said method comprising the application of the apparatus in claims 1 to 5 to null a distortion spike.

7. The method of claim 6 further comprises, the application of the apparatus of claim 5, wherein the ceramic filter delays the carrier by 90 degrees or odd integer multiple thereof.

8. The method of claim 7 further comprises the multiplication of said delayed signal multiplied by the original signal.
